(19) United States
(12) Patent Application Publication
(10) Pub. No.: US 2009/0314066 A1
(43) Pub. Date: Dec. 24, 2009

(54) SENSOR DEVICE FOR AND A METHOD OF SENSING PARTICLES

(75) Inventors: Jeroen Hans Nieuwenhuis, Waalre (NL); Menno Willem Jose Prins, Rosmalen (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/441,568

(22) PCT Filed: Sep. 12, 2007
(86) PCT No.: PCT/IB07/53679

§ 371 Date: Mar. 17, 2009

(30) Foreign Application Priority Data
Sep. 20, 2006 (EP) 06120934.2

(51) Int. Cl. G01N 15/06; G01R 27/08; G01R 33/09

(52) U.S. Cl. 73/61.71; 324/691; 324/252

(57) ABSTRACT

A GMR based sensor device (100) for sensing first particles (504, 505) e.g. magnetic beads for immuno assay of a sample comprising the first particles (504, 505) and second particles (503) e.g. red blood cells, the sensor device (100) comprising a detection unit (11, 12) adapted to detect a signal which depends on a quantity of the first particles (504, 505) and which depends on a quantity of the second particles (503)″ based on a measurement performed with the sample comprising the first particles (504, 505) and the second particles (503), an estimation unit (30) for estimating information indicative of the quantity of the second particles (503) e.g. haematocrit based on an impedance measurement, and a determining unit (20) adapted for determining the quantity of the first particles (504, 505) based on the detected signal under consideration of the estimated information. The advantage of this arrangement is that whole blood samples may be used.

### FIELD OF THE INVENTION

The invention relates to a sensor device for sensing particles.

The invention further relates to a method of sensing particles.

Moreover, the invention relates to a program element.

Further, the invention relates to a computer-readable medium.

### BACKGROUND OF THE INVENTION

A biosensor may be a device for the detection of an analyte that combines a biological component with a physicochemical or physical detector component.

Magnetic biosensors may use the Giant Magnetoresistance Effect (GMR) for detecting biological molecules being magnetic or being labeled with magnetic beads.

In the following, a biosensor will be explained which may use the Giant Magnetoresistance Effect.

WO 2005/010542 discloses the detection or determination of the presence of magnetic particles using an integrated or on-chip magnetic sensor element. The device may be used for magnetic detection of binding of biological molecules on a micro-array or biochip. Particularly, WO 2005/010542 discloses a magnetic sensor device for determining the presence of at least one magnetic particle and comprises a magnetic sensor element on a substrate, a magnetic field generator for generating an AC magnetic field, a sensor circuit comprising the magnetic sensor element for sensing a magnetic property of the at least one magnetic particle which magnetic property is related to the AC magnetic field, wherein the magnetic field generator is integrated on the substrate and is arranged to operate at a frequency of 100 Hz or above.

US 2005/0112544 discloses a device for detecting cells and/or molecules on an electrode surface. The device detects cells and/or molecules through measurement of impedence changes resulting from the cells and/or molecules. The device includes a substrate having two opposing ends along a longitudinal axis. A plurality of electrode arrays are positioned on the substrate. Each electrode array includes at least two electrodes, and each electrode is separated from at least one adjacent electrode in the electrode array by an expanse of non-conductive material. The device also includes electrically conductive traces extending substantially longitudinally to one of the two opposing ends of the substrate without intersecting another trace. Each trace is in electrical communication with at least one of the electrode arrays.

However, the sensitivity of such detectors may still be insufficient under undesired circumstances.

### OBJECT AND SUMMARY OF THE INVENTION

It is an object of the invention to provide a sensor with a sufficient accuracy.

In order to achieve the object defined above, a sensor device for sensing particles, a method of sensing particles, a program element, and a computer-readable medium according to the independent claims are provided.

According to an exemplary embodiment of the invention, a sensor device for sensing first particles of a sample comprising the first particles and second particles is provided, the sensor device comprising a detection unit adapted to detect a signal which depends on a quantity of the first particles and which depends on a quantity of the second particles based on a measurement performed with the sample comprising the first particles and the second particles, an estimation unit for estimating information indicative of the quantity of the second particles based on an impedance measurement, and a determining unit adapted for determining the quantity of the first particles based on the detected signal under consideration of the estimated information.

According to another exemplary embodiment of the invention, a method of sensing first particles of a sample comprising the first particles and second particles is provided, the method comprising detecting a signal which depends on a quantity of the first particles and which depends on a quantity of the second particles by performing a measurement with the sample comprising the first particles and the second particles, estimating information indicative of the quantity of the second particles based on an impedance measurement, and determining the quantity of the first particles based on the detected signal under consideration of the estimated information.

According to still another exemplary embodiment of the invention, a program element is provided, which, when being executed by a processor, is adapted to control or carry out a method of sensing particles having the above mentioned features.

According to yet another exemplary embodiment of the invention, a computer-readable medium is provided, in which a computer program is stored which, when being executed by a processor, is adapted to control or carry out a method of sensing particles having the above mentioned features.

The electronic sensing scheme according to embodiments of the invention can be realized by a computer program, that is by software, or by using one or more special electronic optimization circuits, that is in hardware, or in hybrid form, that is by means of software components and hardware components.

According to an exemplary embodiment, a detection unit may detect a signal which may be indicative of the presence and the concentration/amount/quantity of first particles to be detected (for instance proteins labelled with a magnetic bead). However, the signal detected by the detection unit (for instance a magnetic detector, like an GMR sensor) may also include contributions of second particles (blood cells, for instance) which may be present in the fluidic sample (like a blood sample) apart from the first particles. Therefore, the presence of the second particles may disturb the measurement of the quantity of the first particles, since the signal detected by the detection unit may be dependent on the second particles as well. In order to improve the accuracy of the detection, an estimating unit may be foreseen for performing an impedance measurement adapted in such a manner that selectively the volume contribution of the second particles in the sample may be calculated, and a corresponding contribution of this volume of second particles may be subtracted from the measured detection signal. In other words, the estimated information may be used to correct a detection signal or to calibrate a detection or to compensate signal contributions of the second particles from a detection signal.

According to an exemplary embodiment, it may be dispensable to remove the second particles (for instance blood cells) from the sample (for instance a blood sample) including the first particles (for instance comprising magnetically detectable molecules) before analyzing the sample, thereby significantly simplifying the analysis. Thus, it may not be necessary to (bio)chemically treat the sample to remove disturbing second particles before detecting the first particles. In contrast to this, a correction for a disturbing influence of the second particles on the measurement of the first particles may be carried out by mathematically removing or suppressing the influence of the second particles to the detection signal. For this purpose, an impedance measurement may be carried out specifically for quantifying the second particles for calibrating or correcting a magnetic sensor measurement intending to quantify the first particles.

According to an exemplary embodiment, a magnetic biosensor having a correction feature to at least partially compensate cell content contributions to a measurement signal may be provided. In the field of biosensing, detection techniques may be advantageous that allow a rapid and sensitive detection of biochemical components in raw samples like whole blood. Magnetic biosensing is an appropriate technique to achieve this goal, due to the non-magnetic nature of many biologic samples.

Taking as an example the measurement of Troponin in blood, the Troponin concentration may be conventionally determined in plasma or serum. Plasma may denote blood from which cells have been removed, generally by centrifugation. The cell content in blood may be several tens of percents, mainly due to the high content of red blood cells, the so-called haematocrit, which depends on parameters such as the condition and the sex of the patient. So, conventional laboratory-based Troponin assays may be performed in the absence of the cellular content of the blood.

In a rapid sensor system according to an exemplary embodiment of the invention, which may also be used outside a laboratory, sample handling may be very simple and process steps may be integrated into a cartridge. Integration of a cell removal process may be difficult, for instance centrifugation may require complicated mechanics, and filtration may require a large sample volume and may risk rupturing of a fraction of the cells. Integration of cell removal may be preferably omitted, in order to simplify the cartridge and to reduce or minimize the duration of the test. Thus, embodiments of the invention may make it possible to measure particles of interest (for instance glucose) directly in whole blood, when being present in milli molar pro litre concentrations, and also with significantly smaller concentrations.

Therefore, embodiments of the invention may enable sensitive and rapid outside laboratory testing of low concentration markers such as Troponin in whole blood, by carrying out a correction of a measured signal to mathematically calculate contributions of particles of the sample which distinguish from the particles under examination, allowing for a removal or suppression of such undesired influences.

Therefore, a rapid, reliable and easy to use sensor system may be provided that may allow accurate measurements of target concentration even in the presence of volume occupying entities in the fluidic sample. Examples for such volume occupying entities in the fluid may be cells, or aggregated or coagulated materials in blood. Other examples are food remains, smoke, or cells in saliva, crystals in urine, fibres in food or feed samples, cells or tissue elements in a sample of interstitial fluid, particles in nasal swab, or solid or gaseous entities in the original sample or such entities acquired during sample taking or sample processing.

Difficulties—which may be overcome at least partially by embodiments of the invention—caused by the presence of volume occupying entities are that the target concentration in the sample is reduced due to the blocked volume fraction, and that these entities may hinder the binding of molecules and labels to the sensor surface. These phenomena may deteriorate the accuracy (i.e. the coefficient of variation) of the target concentration measurement by the biosensor system, and may be suppressed according to exemplary embodiments of the invention.

Impedance measurement is an analytical technique for counting and sizing individual particles. An apparatus based on this technique which may be implemented according to exemplary embodiments of the invention is a Coulter counter. The term “Coulter counter” may be denoted as an apparatus for counting and sizing particles and cells. It may be used, for example, for bacteria or prokaryotic cells. The counter may detect a change in electrical conductance of a small aperture as fluid containing cells are drawn through. The cell may alter the effective cross-section of the conductive channel, thereby influencing the measurement. In a Coulter counter, size may be determined by measuring the impedance change caused by the displacement of conductive liquids by particles. For example, blood cells in a sample volume of blood may be counted.

In the case of cells it has been shown (see for instance S. Gawad, M. Heuschkel, Y. Leung-Ki, R. Iuzzolino, L. Schild, Ph. Lerch, Ph. Renaud, “Fabrication of a Microfluidic Cell Analyzer in a Microchannel using Impedance Spectroscopy”, Proc. of 1st Annual International IEEE-EMBS Conference, Oct. 12-14, 2000, Lyon, France; A. R. Varlan, P. Jacobs, B. Sansen, Sensors and Actuators B34, pages 258-264, 1996) that cell volume may be measured when frequencies are used below 100 kHz. At higher frequencies (around 1 MHz, or above larger than 20 MHz) the capacitance of the cell membrane may start to dominate the impedance of the cell. Thus, as long as the frequency is kept low enough, for instance below 100 kHz, the concentration of solids can be measured using impedance measurements.

To implement such an impedance measurement method in a device according to an exemplary embodiment of the invention for determining the fraction of solids in a sample with unknown background conductivity, it may be advantageous to know the conductivity of the suspending medium as well. Therefore, it is possible to perform a measurement method that can differentially measure the conductivity of the medium. One way (for instance disclosed in A. R. Varlan, P. Jacobs, B. Sansen, Sensors and Actuators B34, pages 258-264, 1996) is to measure the conductivity of the medium without the influence of solid content, by putting a semipermeable membrane over the electrodes. The thickness of the membrane and the spacing of the electrodes may be adjusted or optimized such that the electric field lines may be confined to the thickness of the membrane. The membrane may keep the solid content away from the measurement region. This may allow to measure the conductivity of the medium, independent from the concentration of solids.

In the case of the biosensor, it may be inappropriate to use a semipermeable membrane, because antibodies and magnetic bead should bind very close to the GMR sensor. Furthermore, the additional procedures required to apply the membrane may add complexity. Beyond this, the application of a membrane cannot address efficiently the problem of sedimentation of solid content.

According to an exemplary embodiment of the invention, it is possible to use geometries of widely spaced electrodes and of narrowly spaced electrodes to measure the impedance of the entire sample and to measure the impedance close to the surface of the sensor.

Directly after injection of the sample, the solid content may still be distributed homogeneously over the volume. The widely spaced electrodes may measure the impedance of the entire sample, including the influence of the solid content. The narrowly spaced electrodes may now measure the impedance of the suspending medium, since the solid content did not sediment towards the surface yet. Based on the impedance of the medium and the impedance of the entire sample, the volume fraction of the cell content can be calculated to compensate the readings of the biosensor.

By continuing to monitor the impedance between the narrowly spaced electrodes, the tendency of the solid components to sediment towards the sensor surface can be measured. When solid content sediments onto the narrowly spaced electrodes, its presence may be detected by a change (for instance an increase) in impedance.

Thus, directly after injection of the sample, the volume fraction of solids may be measured, and during the experiment the sedimentation of solid content may be monitored with the same (or other) electrodes.

Therefore, according to an exemplary embodiment, a method to measure the volume fraction of solids in a sample based on impedance measurements with integrated electrodes may be provided. Using the same electrodes, also the tendency of the sample to sediment towards the sensor surface can be monitored. Both measurements may allow to compensate for the influence of solids in measurements with the biosensor. This may be a crucial aspect from a point of care measurement, when a sample pre-treatment procedure cannot be used or is not desirable.

Exemplary embodiments may have the advantage that no additional fabrication procedures are required to integrate the electrodes in a biosensor. The same electrodes can be used to compensate for both the volume of the solid content and for the tendency of the solid content to sediment. The accuracy of the biosensor in a raw sample can therefore be significantly improved.

Next, further exemplary embodiments of the sensor device will be explained. However, these embodiments also apply to the method, to the program element and to the computer-readable medium.

The estimation unit may be adapted for estimating a volume fraction of the second particles in the sample based on the impedance measurement. The electric conductivity/non-conductivity or other electric properties of the second particles (for instance of blood cells) may be used for estimating the volume fraction of the second particles, since the impedance (ohmic portion, capacitive portion, and/or inductive portion) may be influenced by the amount of the second particles.

The estimation unit may be adapted to measure a time-dependence of the impedance of the sample. During a measurement, the impedance of the sample may be modified (due to effects like sedimentation, etc.). Therefore, such a dynamical measurement may be carried out, for instance to compensate for sensor accuracy modifications which may result from effects like sedimentation of solid particles in a sample, or the like.

The estimation unit may further be adapted to measure the impedance of essentially the entire sample in a first measurement mode, and may be adapted to selectively measure the impedance of a suspending medium of the sample in a second measurement mode. For example, directly after having injected the sample into the sensor device (for instance after having filled-in the sample with a pipette), the components in the sample are essentially equally distributed. In this measurement mode, an impedance of the entire sample may be measured. However, since the solid or heavy particles have not yet sedimented at such an early point of time, a measurement in a second measurement mode which is performed at a position close to a surface of the sensor may allow to determine the impedance of the suspending medium, that is the sample without the first and the second particles. Such a suspending medium may be a buffer, a carrier fluid or the like in which the particles are dissolved or contained.

The estimation unit may be adapted to selectively measure the impedance of the second particles in a third measurement mode. After sedimentation of the, for instance, relatively large or heavy second particles (for instance blood cells) onto a surface of the sensor, a measurement of the impedance close to the surface of the sensor may be carried out so as to measure separately the impedance of the second particles.

The measurement in one of the first to third measurement modes may provide valuable (complementary) information about components of the sample.

The estimation unit may comprise electrodes adapted for measuring the impedance of the sample. Such at least two electrodes may be supplied with an exciting electric signal, for instance a time-dependent signal or an oscillating signal or a constant signal. Applying such a signal and/or measuring a response signal may then allow to determine the impedance.

The electrodes may comprise first electrodes and may comprise second electrodes. The first electrodes may be sensitive for a volume of the sample which is larger than a volume of the sample for which the second electrodes are sensitive. This property may be adjusted by selecting the geometrical properties of the electrodes, like electrode surface area, distances between individual electrodes, number of electrodes, or the like. Therefore, by selecting the geometrical properties of the electrodes, their spatial sensitivity can be adjusted.

The electrodes may comprise (for instance two) first electrodes arranged at a first distance from one another and may comprise (for instance two or more than two) second electrodes arranged at a second distance from one another, wherein the first distance and the second distance may differ. Particularly, the first distance may be larger than the second distance. By providing the electrodes with a larger distance from one another, the active area which may be captured by the electrodes during an impedance measurement may be varied.

The first electrodes may be adapted to measure an impedance of essentially the entire sample. The largely spaced electrodes which may also have a relatively large size or extension of the electrode surfaces may therefore be adapted to measure a large portion or the entire volume of the sample.

In contrast to this, the second electrodes may be adapted to measure an impedance of a part of the sample being arranged in a vicinity of the second electrodes. Therefore, the information measurable by the second electrodes may differ from the information measurable by the first electrodes. The active area of the second electrodes may be spatially restricted due to their small distance from one another, so that only a part of the sample may be measured.

The first electrodes and/or the second electrodes may be provided on and/or in a substrate. Therefore, the electrodes may be provided as embedded electrodes which may be integrated on or in a surface of the substrate. This may allow to manufacture the sensor device with low effort and with a small dimension.

The first electrodes may have a size which is larger than a size of the second electrodes. For example, the first electrodes may have an essentially rectangular cross-sectional shape with one side being essentially longer than the other side, for instance with a side ratio of more than five to one. The second electrodes may be arranged, for instance, in a matrix-like manner and may each have an essentially square surface. Such a matrix of second electrodes may be arranged between two essentially parallel aligned first electrodes.

At least a part of the electrodes may optionally comprise an electrically conductive core and a membrane covering the electrically conductive core. The (semipermeable) membrane may be impermeable for the second particles which may be significantly larger than the first particles. By taking this measure, it may be avoided that the second particles may accumulate in a direct environment of the electrically conductive core (for instance made of a metallic material like gold), thereby allowing the electrodes to measure the impedance caused by the second particles.

The detection unit may comprise a magnetic field generator unit adapted for generating a magnetic field for magnetically exciting the first particles and may comprise a sensing unit adapted for sensing the signal influenced by the first particles. Such a magnetic field generator unit may be a magnetic wire to which a current may be applied. Consequently, in an environment of such a wire through which a current is flowing, a magnetic field may be generated which may influence the (magnetic) first particles, to bring them into an excited magnetic state. Consequently, a signal measured by a sensing unit (for instance an GMR sensor) may be modulated, thereby allowing the sensing unit to detect a signal which is indicative of or which depends on the quantity or amount of the first particles in the sample.

The sensing unit may be adapted for sensing the magnetic particles based on an effect of the group consisting of GMR, AMR, and TMR. Particularly, a magnetic field sensor device may make use of the Giant Magnetoresistance Effect (GMR) being a quantum mechanical effect observed in thin film structures composed of alternating (ferro)magnetic and non-magnetic metal layers. The effect manifests itself as a significant decrease in resistance from the zero-field state, when the magnetization of adjacent (ferro)magnetic layers are antiparallel due to a weak anti-ferromagnetic coupling between layers, to a lower level of resistance when the magnetization of the adjacent layers align due to an applied external field. The spin of the electrons of the nonmagnetic metal align parallel or antiparallel with an applied magnetic field in equal numbers, and therefore suffer less magnetic scattering when the magnetizations of the ferromagnetic layers are parallel. Examples for biosensors making use of the Giant Magnetoresistance Effect (GMR) are disclosed in WO 2005/010542 or WO 2005/010543.

The magnetic sensor device may be adapted for sensing magnetic beads attached to biological molecules. Such biological molecules may be proteins, DNA, genes, nucleic acids, polypeptides, hormones, antibodies, etc.

The magnetic sensor device may be adapted as a magnetic biosensor device, that is to say as a biosensor device operating based on a magnetic detection principle.

At least a part of the sensor device may be realized as a monolithically integrated circuit. Therefore, components of the magnetic sensor device may be monolithically integrated in a substrate, for instance a semiconductor substrate, particularly a silicon substrate. However, other semiconductor substrates are possible, like germanium, or any group III-group V semiconductor (like gallium arsenide or the like).

The sensor can be any suitable sensor based on the detection of the magnetic properties of the particle on or near to a sensor surface, e.g. a coil, a wire, magneto-resistive sensor, magneto-strictive sensor, Hall sensor, planar Hall sensor, flux gate sensor, SQUID, magnetic resonance sensor, etc.

The detection can occur with or without scanning of the sensor element with respect to the (bio)sensor surface.

Measurement data can be derived as an end-point measurement, as well as by recording signals for instance kinetically or intermittently.

Devices and/or methods according to exemplary embodiments of the invention can be used with several biochemical assay types, e.g. binding/unbinding assay, sandwich assay, competition assay, displacement assay, enzymatic assay, etc.

In addition or alternatively to molecular assays, also larger moieties can be detected, e.g. cells, viruses, or fractions of cells or viruses, tissue extract, etc.

The device, methods and systems according to exemplary embodiments of the invention are suited for sensor multiplexing (i.e. the parallel use of different sensors and sensor surfaces), label multiplexing (i.e. the parallel use of different types of labels) and chamber multiplexing (i.e. the parallel use of different reaction chambers).

The device, methods and systems according to exemplary embodiments of the invention can be used as rapid, robust, and easy to use point-of-care biosensors for small sample volumes. The reaction chamber can be a disposable item to be used with a compact reader. Also, the device, methods and systems of the present invention can be used in automated high-throughput testing. In this case, the reaction chamber is e.g. a well plate or cuvette, fitting into an automated instrument.

The aspects defined above and further aspects of the invention are apparent from the examples of embodiment to be described hereinafter and are explained with reference to these examples of embodiment.

### BRIEF DESCRIPTION OF THE DRAWINGS

The invention will be described in more detail hereinafter with reference to examples of embodiment but to which the invention is not limited.

FIG. 1 to FIG. 6 illustrate sensor devices according to exemplary embodiments of the invention.

### DESCRIPTION OF EMBODIMENTS

The illustration in the drawing is schematically. In different drawings, similar or identical elements are provided with the same reference signs.

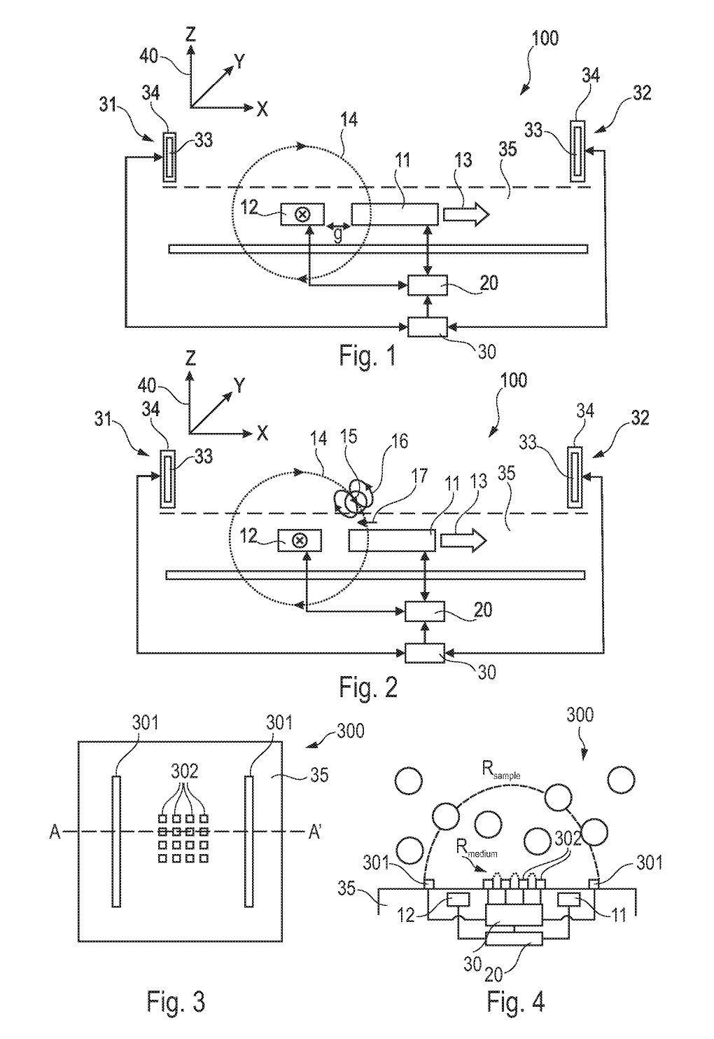

In a first embodiment the device 100 according to the present invention is a biosensor and will be described with respect to FIG. 1 and FIG. 2.

The biosensor detects magnetic particles in a sample such as a fluid, a liquid, a gas, a visco-elastic medium, a gel or a tissue sample. The magnetic particles can have small dimensions. With nano-particles are meant particles having at least one dimension ranging between 0.1 nm and 1000 nm, preferably between 3 nm and 500 nm, more preferred between 10 nm and 300 nm. The magnetic particles can acquire a magnetic moment due to an applied magnetic field (e.g. they can be paramagnetic). The magnetic particles can be a composite, e.g. consist of one or more small magnetic particles inside or attached to a non-magnetic material. As long as the particles generate a non-zero response to a modulated magnetic field, i.e. when they generate a magnetic susceptibility or permeability, they can be used.

The device may comprise a substrate 35 and a circuit, e.g. an integrated circuit.

A measurement surface of the device is represented by the dotted line in FIG. 1 and FIG. 2. In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes glass, plastic, ceramic, silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. In the following reference will be made to silicon processing as silicon semiconductors are commonly used, but the skilled person will appreciate that the present invention may be implemented based on other semiconductor material device(s) and that the skilled person can select suitable materials as equivalents of the dielectric and conductive materials described below.

The circuit may comprise a magneto-resistive sensor 11 as a sensor element and a magnetic field generator in the form of a conductor 12. The magneto-resistive sensor 11 may, for example, be a GMR or a TMR type sensor. The magneto-resistive sensor 11 may for example have an elongated, e.g. a long and narrow stripe geometry but is not limited to this geometry. Sensor 11 and conductor 12 may be positioned adjacent to each other within a close distance g. The distance g between sensor 11 and conductor 12 may for example be between 1 nm and 1 mm; e.g. 3 μm. The minimum distance is determined by the IC process.

In FIG. 1 and FIG. 2, a coordinate system 40 is introduced to indicate that if the sensor device is positioned in the xy plane, the sensor 11 mainly detects the x-component of a magnetic field, i.e. the x-direction is the sensitive direction of the sensor 11. The arrow 13 in FIG. 1 and FIG. 2 indicates the sensitive x-direction of the magneto-resistive sensor 11 according to the present invention. Because the sensor 11 is hardly sensitive in a direction perpendicular to the plane of the sensor device, in the drawing the vertical direction or z-direction, a magnetic field 14, caused by a current flowing through the conductors 12, is not detected by the sensor 11 in absence of magnetic nano-particles 15. By applying current sequences to the conductor 12 in the absence of magnetic nano-particles 15, the sensor 11 signal may be calibrated. This calibration may be performed prior to a measurement.

When a magnetic material (this can e.g. be a magnetic ion, molecule, nano-particle 15, a solid material or a fluid with magnetic components) is in the neighborhood of the conductors 12, it develops a magnetic moment m indicated by the field lines 16 in FIG. 2.

The magnetic moment m then generates dipolar stray fields, which have in-plane magnetic field components 17 at the location of the sensor 11. Thus, the nano-particle 15 deflects the magnetic field 14 into the sensitive x-direction of the sensor 11 indicated by arrow 13 (FIG. 2). The x-component of the magnetic field Hx which is in the sensitive x-direction of the sensor 11, is sensed by the sensor 11 and depends on the number of magnetic nano-particles 15 and the conductor current Ic.

For further details of the general structure of such sensors, reference is made to WO 2005/010542 and WO 2005/010543.

FIG. 1 shows the sensor device 100 for sensing first particles (for instance proteins attached to magnetic beads) of a fluidic sample comprising the first particles and second particles (for instance blood cells). Thus, the sample may be a blood sample.

The sensor device 100 comprises a detection unit formed by the GMR sensor 11 and by the magnetic wire 12 and adapted to detect a signal which depends on the amount of the first particles and which depends on the amount of the second particles in the sample. The magnetic detection signal may be captured by the GMR sensor 11 as a result of the presence of the magnetic beads in an environment of the GMR sensor 11 influenced by the magnetic field 14 generated by the magnetic wire 12.

Separately from this detection unit 11, 12, an estimation unit 30 is provided for estimating information indicative of the quantity of the second particles based on an impedance measurement carried out using electrodes 31, 32. The estimating unit 30 is adapted to apply exciting signals to the electrodes 31, 32 and/or to receive signals from the electrodes 31, 32 indicative of the impedance of the second particles. Such an impedance measurement may help to determine the amount of second particles in the sample, which second particles may disturb the determination of the concentration of the first particles.

As can further be taken from FIG. 1, the estimation unit 30 as well as the magnetic wire 12 and the GMR sensor 11 are coupled to a processor unit 20 (like a microprocessor or a CPU, central control unit) which may serve for determining the quantity of the first particles. This quantity can be derived from the detected signal which may be corrected or calibrated using the estimated information so as to suppress or eliminate the influence of the second particles on the detected signals.

As can be taken from FIG. 1, each of the electrodes 31, 32 comprises an electrically conductive core 33 and a semipermeable membrane 34 enclosing the electrically conductive core 33. The membrane 34 is impermeable for the second particles, but permeable for other components of the sample.

As an alternative to the configuration of FIG. 1, the electrodes 31, 32 may also be integrated within the substrate 35 and may be provided without a membrane 34. The electrodes 31, 32 may be controlled by the estimating unit 30 so that they can measure the conductivity of the second particles. The result of this estimation may be supplied from the estimating unit 30 to the CPU 20, as well as a signal obtained from the actual measurement of the first particles performed by the components 11, 12.

The CPU 20 may then calculate a corrected quantity of first particles by subtracting, from the signal detected during the magnetic measurement, a contribution originating from the second particles. The quantity of the second particles, in turn, may be estimated by the impedance measurement.

In the following, referring to FIG. 3, a sensor device 300 according to another exemplary embodiment of the invention will be explained.

FIG. 3 shows a plan view of the sensor device 300, and FIG. 4 shows a cross-sectional view along a line A-A′ of FIG. 3.

The components of the sensor 300 are integrated in a silicon substrate 35.

FIG. 3 shows first electrodes 301 and second electrodes 302 deposited on a surface of the substrate 35. The first electrodes 301 have a larger size and a larger distance from one another as compared to the second electrodes 302 and are therefore sensitive to a volume of the sample which is larger than a volume of the sample to which the second electrodes 302 are sensitive. The volume of sensitivity is indicated schematically by the reference numerals R_{Medium} and R_{Sample}.

As can be taken from FIG. 3, the first electrodes 301 are designed as (relatively) widely spaced electrodes, and the second electrodes 302 are designed as (relatively) narrowly spaced electrodes. The pair of large electrodes 301 measures the conductivity of the entire sample, whereas the small electrodes 302 are only sensitive to the influence of the suspending medium of the sample. Therefore, it is possible with the configuration shown in FIG. 3 and FIG. 4 to measure separately the conductivity of the suspending medium and the average conductivity of the entire sample, which is defined by the conductivity of the medium on the one hand and by the volume taken up by the second particles (which displace the medium). These items of information can be used to calibrate or correct a measurement performed by the GMR sensor 11 in connection with the magnetic wire 12.

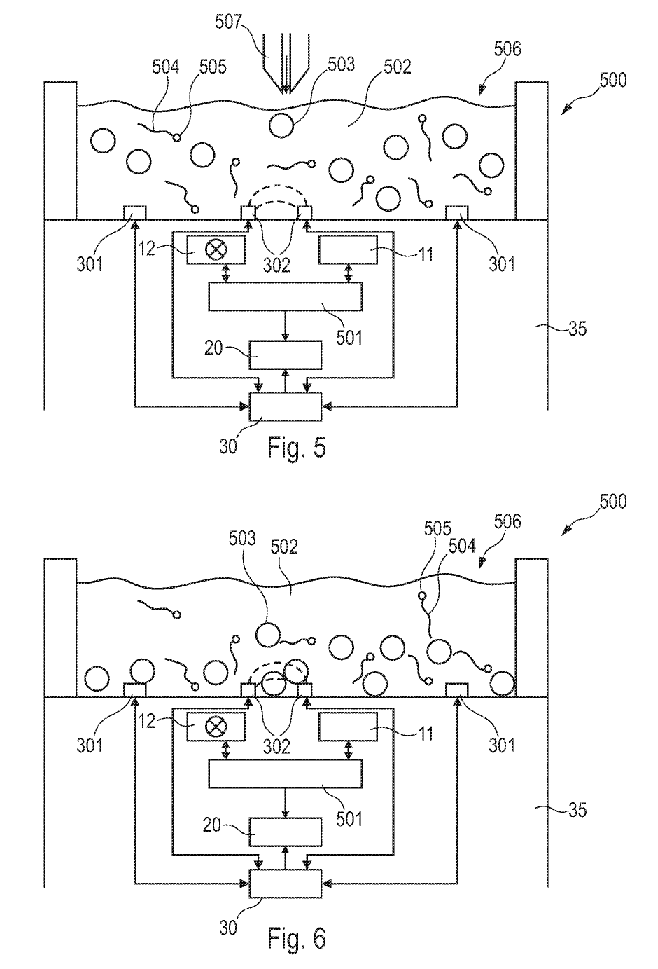

FIG. 5 and FIG. 6 show a cross-sectional view of a sensor device 500 according to an exemplary embodiment in two different operation states.

In the operation state shown in FIG. 5, a sample has just been filled in a container portion 506 of the sensor device 500. For this purpose, a pipette 507 may be used.

As can be taken from FIG. 5, the sample filled in the container portion 506 comprises particles 504 to be detected, namely proteins, which are labelled with magnetic beads 505. As a further component, second particles 503, namely blood cells, are included in the sample. The first particles 504, 505 and the second particles 503 are dissolved in a suspension 502. In the first operation state shown in FIG. 5, the particles 503 to 505 are essentially equally or statistically distributed in the suspension medium 502, since the sample (which may be properly mixed beforehand) has just been filled in the container 506.

Particularly, an environment of the second (narrowly spaced) electrodes 302 is free of the heavy particles 503, since essentially no sedimentation has occurred yet. Therefore, in the operation mode of FIG. 5, the second electrodes 302 measure the electrical conductivity of the suspension medium 502, whereas the first (widely spaced) electrodes 301 may measure a conductivity or impedance of the entire sample 502 to 505.

FIG. 6 shows the sensor device 500 in a second operation state.

The second operation state of FIG. 6 is obtained after waiting a sufficient time. During this time, particularly the heavy and high density second particles 503 have the tendency to sediment at a surface of the substrate 34, thereby influencing the impedance signal detected by the second electrodes 302. Therefore, when detecting the signal with the second electrodes 302 for a sufficiently long time after filling in the sample, sedimentation effects may be measured and may be used optionally for the correction of the measurement, thereby further increasing accuracy. Thus, in the operation mode of FIG. 6, the impedance of the second particles may be measured.

It should be noted that the term “comprising” does not exclude other elements or features and the “a” or “an” does not exclude a plurality. Also elements described in association with different embodiments may be combined.

It should also be noted that reference signs in the claims shall not be construed as limiting the scope of the claims.

1. A sensor device (100) for sensing first particles (504, 505) of a sample comprising the first particles (504, 505) and second particles (503), the sensor device (100) comprising
a detection unit (11, 12) adapted to detect a signal which depends on a quantity of the first particles (504, 505) and which depends on a quantity of the second particles (503) based on a measurement performed with the sample comprising the first particles (504, 505) and the second particles (503);
an estimation unit (30) adapted to estimate information indicative of the quantity of the second particles (503) based on an impedance measurement;
a determining unit (20) adapted for determining the quantity of the first particles (504, 505) based on the detected signal under consideration of the estimated information.

2. The sensor device (100) of claim 1,
wherein the estimation unit (30) is adapted for estimating a volume fraction of the second particles (503) in the sample based on the impedance measurement.

3. The sensor device (100) of claim 1,
wherein the determining unit (20) is adapted for determining an amount of the first particles (504, 505) based on the detected signal under consideration of the estimated information.

4. The sensor device (100) of claim 1,
wherein the determining unit (20) is adapted for determining the quantity of the first particles (504, 505) based on the detected signal by performing a correction using the estimated information.

5. The sensor device (100) of claim 1,
wherein the estimation unit (30) is adapted to measure a time-dependence of the impedance of the sample.

6. The sensor device (100) of claim 1,
wherein the estimation unit (30) is adapted to measure the impedance of essentially the entire sample in a first measurement mode, and is adapted to selectively measure the impedance of a suspending medium (502) of the sample in a second measurement mode.

7. The sensor device (100) of claim 1,
wherein the estimation unit (30) is adapted to selectively measure the impedance of the second particles (503) in a third measurement mode.

8. The sensor device (100) of claim 1,
wherein the estimation unit (30) comprises electrodes (31, 32, 301, 302) adapted for measuring the impedance of the sample.

9. The sensor device (100) of claim 8,
wherein the electrodes comprise first electrodes (301) and comprise second electrodes (302), the first electrodes (301) being sensitive for a volume of the sample which is larger than a volume of the sample for which the second electrodes (302) are sensitive.

10. The sensor device (100) of claim 8,
wherein the electrodes comprise first electrodes (301) arranged at a first distance from one another and comprise second electrodes (302) arranged at a second distance from one another.

11. The sensor device (100) of claim 10,
wherein the first distance is larger than the second distance.

12. The sensor device (100) of claim 10,
wherein the first electrodes (301) are adapted to measure an impedance of essentially the entire sample.

13. The sensor device (100) of claim 10,
wherein the second electrodes (302) are adapted to measure an impedance selectively of a part of the sample being arranged in a vicinity of the second electrodes (302).

14. The sensor device (100) of claim 10,
wherein the first electrodes (301) and the second electrodes (302) are provided on and/or in a substrate (35).

15. The sensor device (100) of claim 10,
wherein the first electrodes (301) have a size which is larger than a size of the second electrodes (302).

16. The sensor device (100) of claim 8,
wherein the electrodes (31, 32) comprise an electrically conductive core (33) and a membrane (34) at least partially covering the electrically conductive core (33), wherein the membrane (34) is impermeable for the second particles (503).

17. The sensor device (100) of claim 1,
wherein the first particles (504, 505) are significantly smaller than the second particles (503).

18. The sensor device (100) of claim 1,
wherein the detection unit comprises
a magnetic field generator unit (12) adapted for generating a magnetic field for magnetically exciting the first particles (504, 505);
a sensing unit (11) adapted for sensing the signal influenced by the first particles (504, 505).

19. The sensor device (100) of claim 1,
wherein the detection unit (11, 12) is adapted for detecting the first particles (504, 505) based on the Giant Magnetoresistance Effect.

20. The sensor device (100) of claim 1,
adapted as a biosensor device.

21-28. (canceled)
